(19) United States
(12) Patent Application Publication
(10) Pub. No.: US 2020/0157678 A1
(43) Pub. Date: May 21, 2020

(54) LIFT PIN HOLDER ASSEMBLIES AND BODIES INCLUDING LIFT PIN HOLDER ASSEMBLIES

(71) Applicant: Applied Materials, Inc., Santa Clara, CA (US)

(72) Inventors: Jason M. SCHALLER, Austin, TX (US); Jeffrey Charles BLAHNIK, Volente, TX (US); Jeongmin LEE, San Ramon, CA (US)

(21) Appl. No.: 16/584,452

(22) Filed: Sep. 26, 2019

Related U.S. Application Data
(60) Provisional application No. 62/767,823, filed on Nov. 15, 2018.

(51) Int. Cl. C23C 16/458; H01L 21/687

(52) U.S. Cl. CPC C23C 16/4586; H01L 21/68785; H01L 21/68742

(57) ABSTRACT

Embodiments of the present disclosure generally relate to lift pin holders, lift pin holder assemblies, and substrate supports containing the lift pin holder and/or the lift pin holder assembly. In one or more embodiments, a lift pin holder contains a cap having a first outside diameter, a base coupled to the cap where the base has a second outside diameter, a first bore formed axially through the cap and the base where the first bore has a sidewall, and a plurality of second bores extending from the sidewall of the first bore to an outer surface of the base where a spring-loaded member is disposed within each of the second bores.

### CROSS-REFERENCE TO RELATED APPLICATIONS

This application claims benefit to U.S. Appl. No. 62/767,823, filed on Nov. 15, 2018, which is herein incorporated by reference.

### BACKGROUND

### Field

Embodiments of the present disclosure generally relate to process chambers used to fabricate semiconductor devices, and in particular to lift pins and lift pin assemblies for use in process chambers.

### Description of the Related Art

Chemical vapor deposition (CVD) is generally employed to deposit a film on a substrate such as a semiconductor wafer or a transparent substrate used for flat panel displays. CVD is generally accomplished by introducing process gasses into a vacuum chamber where a substrate is positioned on a substrate support.

Substrate supports in CVD chambers include lift pins. The lift pins are configured to be raised and lowered in order to raise a substrate from, or lower a substrate onto, the substrate support. The lift pins can be inserted and removed in the substrate support by directly accessing a lift pin holder. However, in some configurations of substrate supports, the lift pin holder may not be directly accessible, creating a challenge for the lift pin insertion. Additionally, when the lift pin is removed from the substrate support assembly, the holder can be inadvertently moved, thereby damaging the substrate support.

Thus, there is a need for improved lift pins, lift pin holders, and lift pin holder assemblies.

### SUMMARY

Embodiments of the present disclosure generally relate to lift pin holders, lift pin holder assemblies, and substrate supports containing the lift pin holder and/or the lift pin holder assembly. In one or more embodiments, a lift pin holder contains a cap having a first outside diameter, a base coupled to the cap where the base has a second outside diameter, a first bore formed axially through the cap and the base where the first bore has a sidewall, and a plurality of second bores extending from the sidewall of the first bore to an outer surface of the base where a spring-loaded member is disposed within each of the second bores.

In some embodiments, an assembly contains a lift pin and a lift pin holder. The lift pin contains an elongated portion having an elongated portion length and an elongated portion diameter and a second portion adjacent to the elongated portion and having a locking mechanism. The lift pin holder contains a cap having a first outside diameter, a base coupled to the cap where the base has a second outside diameter, a first bore formed axially through the cap and the base where the first bore having a sidewall, and a plurality of second bores extending from the sidewall of the first bore to an outer surface of the base, where a spring-loaded member is disposed within each of the second bores.

In other embodiments, a substrate support contains a lift pin holder assembly and a member coupled to a base of a lift pin holder. The lift pin holder assembly contains a lift pin and the lift pin holder. The lift pin contains an elongated portion having an elongated portion length and an elongated portion diameter and a second portion adjacent to the elongated portion and having a locking mechanism. The lift pin holder contains a cap having a first outside diameter, the base coupled to the cap, where the base having a second outside diameter, a first bore formed axially through the cap and the base, where the first bore having a sidewall, and a plurality of second bores extending from the sidewall of the first bore to an outer surface of the base where a spring-loaded member is disposed within each of the second bores.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1E depict schematic views of a lift pin holder, according to one or more embodiments.

FIGS. 2A-2D depict schematic views of retaining mechanisms in lift pin holders, according to one or more embodiments.

FIG. 3 depicts a schematic view of a lift pin, according to one or more embodiments.

FIGS. 4A-4F depict partial schematic views of lift pins, according to one or more embodiments.

FIG. 5A depicts a partial cross-section view of a process chamber that includes a substrate support containing one or more lift pin holder assemblies, according to one or more embodiments.

FIGS. 5B and 5C depict partial schematic views of a substrate support in extended and retracted positions, respectively, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Process chambers used in semiconductor device fabrication include bodies that have mechanisms used for lifting substrates to facilitate substrate handling and transfer. The substrate handling and transfer mechanisms can be in the form of lift pins. Life pins can be mounted in lift pin holders contained in a body such as a substrate support, and at least a portion of the substrate support can be extended or retracted to extend or retract the lift pins. Extending or retracting lift pins moves the substrate positioned on the body to away from or on to the body. Conventional substrate supports include for example, an O-ring or a C-clamp in the substrate handling mechanism. However, the O-ring may not be able to withstand elevated process temperatures. Additionally, the C-clamp is disposed such that removing the lift pin can also damage other components of the substrate support. Further, process chambers such as chemical vapor deposition (CVD), atomic layer deposition (ALD), and other semiconductor fabrication chambers can have small internal volumes with limited vertical clearance. The limited vertical clearance presents a challenge for substrate support design and assembly, including the placement and removal of lift pins. The systems and methods discussed herein are directed towards substrate supports that include one or more lift pins secured in one or more lift pin holders, referred to herein as “lift pin holder assemblies.” Using the lift pin holder assemblies discussed herein, lift pins can be removed and replaced without disassembling or damaging substrate supports across various types of semiconductor fabrication chambers.

According to some embodiments of the present disclosure, a lift pin holder is assembled into the substrate support along with components optionally including a ground plate, a spacer, and a heater. A lift pin is subsequently inserted through the substrate support into the lift pin holder and secured in the lift pin holder. Lift pins can be installed and later removed from the substrate support by coupling and uncoupling a retaining mechanism of the lift pin holder to each lift pin. The retaining mechanism of the lift pin holder includes at least one spring-loaded member. The retaining mechanism secures the lift pin within the lift pin holder and enables the advancement and retraction of the lift pin above and below a top surface of the substrate support without releasing the lift pin. During maintenance or other operations where the lift pin is removed and/or replaced, the retaining mechanism allows for the lift pin to be removed and/or replaced without damaging other components. That is, the spring-loaded members of the retaining mechanism allow the lift pin to be released without damaging the substrate support while the lift pin holder remains in place in the substrate support. A new lift pin can then be inserted in the substrate support and retained in the lift pin holder via the retaining mechanism.

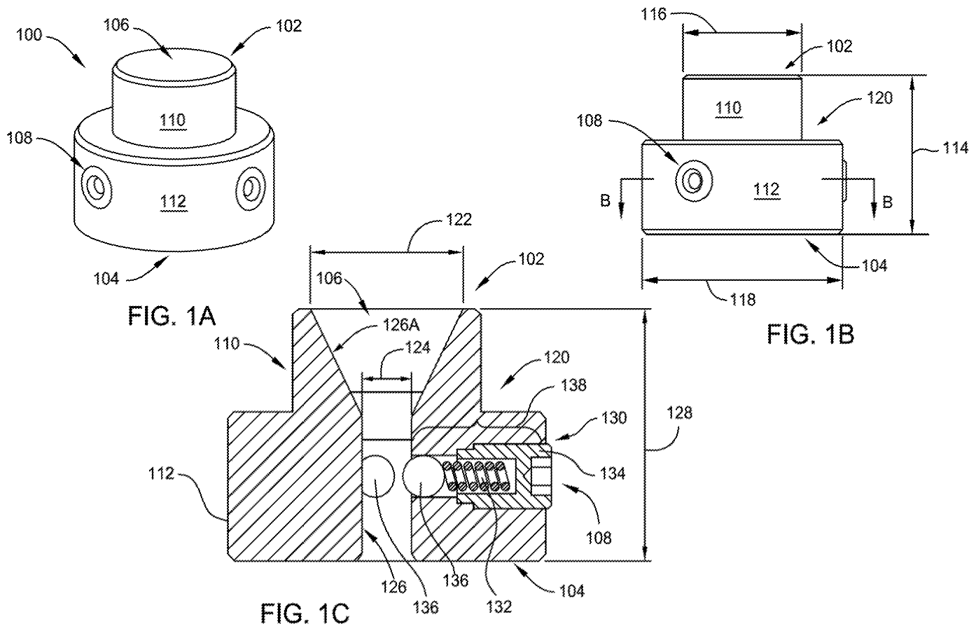

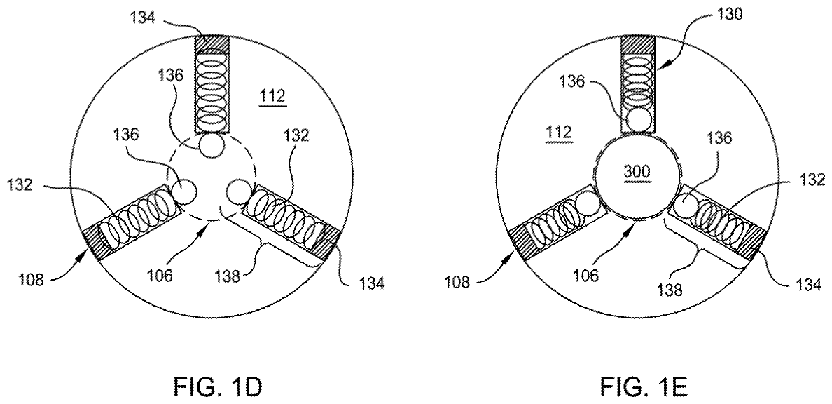

FIGS. 1A-1E depict schematic views of a lift pin holder 100 according to embodiments of the present disclosure. FIG. 1A is an isometric view of a lift pin holder 100, which can alternately be referred to as a weight or a weighted holder. The lift pin holder 100 includes a cap 110, a base 112 coupled to the cap 110, and a retaining mechanism 108. The lift pin holder 100 further includes a through-bore 106 extending axially from a first holder end 102 of the lift pin holder 100 to a second holder end 104 of the lift pin holder 100. The through-bore 106 can have a consistent diameter or a varying diameter along an axial length thereof. Each of the cap 110 and the base 112 can independently be fabricated from and/or contain one or more metals or metallic materials, such as stainless steel. The lift pin holder 100 secures members such as lift pins discussed below in the through-bore 106 via the retaining mechanism 108.

FIG. 1B is a side view of the lift pin holder 100. FIG. 1B shows the first holder end 102, the second holder end 104, and the retaining mechanism 108. FIG. 1B further shows an overall holder length 114, a cap outside diameter 116, and a base outside diameter 118. FIG. 1B further shows a transitional surface 120 in between the cap 110 and the base 112. While the transitional surface 120 in FIG. 1B is shown as being substantially parallel to the first holder end 102 and the second holder end 104, it is contemplated that other transitional surface 120 geometries are possible. Thus, in other examples, the transitional surface 120 can have a bowed, curved, stepped, or other cross-sectional geometry. In examples depicted in FIG. 1B, the cap outside diameter 116 is less than the base outside diameter 118. In some examples, the cap outside diameter 116 is about 30% to about 90% of the base outside diameter 118.

FIG. 1C is a cross-sectional view of FIG. 1B taken along line A-A in FIG. 1B. FIG. 1C shows the through-bore 106 which has a first diameter 122 at a first holder end 102. The diameter of the through-bore 106 tapers downward through the cap 110 to a second diameter 124, to form a sidewall 126 having a frustoconical shape. The through-bore 106 continues at the second diameter 124, an inner diameter which can be a constant inner diameter, axially through the base 112. The overall length 128 of the through-bore 106 is measured from the first holder end 102 to the second holder end 104. In one or more examples, as shown in FIG. 1C, the first diameter 122 of the through-bore 106 is larger than the second diameter 124, and a first sidewall portion 126A is an angled, transitional surface between the two diameters. In other examples, not shown here, the first diameter 122 is substantially similar to (differing by less than 5%) or the same as the second diameter 124. In this example, the first sidewall portion 126A would be substantially perpendicular to a plane of the first holder end 102, similar to what is shown for the sidewall 126 of the second diameter 124 in FIG. 1C. The tapered diameter of the first sidewall portion 126A facilitates guidance of a lift pin (not shown) into the lift pin holder 100 during a lift pin replacement operation. In this example, the overall length 128 of the through-bore 106 can be substantially similar to the overall holder length 114 shown in FIG. 1B. In other examples, the overall length 128 of the through-bore 106 can be less than the overall holder length 114 shown in FIG. 1B. In this example, the through-bore 106 extends partially through the lift pin holder 100 without extending through the second holder end 104.

The lift pin holder 100 includes one or more bores 130 extending outward from the sidewall 126. Each of the one or more bores 130 can house a spring-loaded member 138 therein. In some examples, each bore 130 extends from the sidewall 126 entirely through the base 112, e.g., to the outside surface of the base 112. In other examples, each bore 130 extends outwards from the sidewall 126 but extends partially through the base 112. The spring-loaded member 138 shown in the retaining mechanism 108 is positioned in a bore 130 formed parallel to a radius of the base 112, perpendicularly from an axis of the through-bore 106. In alternate embodiments, one or more spring-loaded members 138 (and corresponding bores 130) of the retaining mechanism 108 can be configured at different angles other than 90° relative to a radius extending perpendicularly from an axis of the through-bore 106.

Each spring-loaded member 138 of the retaining mechanism 108 includes a spring 132 and a movement member 136. Each spring-loaded member 138 can further include a spring housing 134 which secures the spring 132 inside of the base 112. In one or more examples, the spring housing 134 includes an outer threaded surface for engaging corresponding threads of a bore 130. Each spring housing 134 may include groove or recess for receiving a spring 132 therein. Each of the spring 132 and the spring housing 134 can be fabricated from and/or contain one or more metals or metallic materials, such as stainless steel. The movement member 136 is disposed on a radially inward end of the spring 132 adjacent to the through-bore 106 in the base 112. The movement member 136 can be a sphere or can be defined by a different geometry. The movement member 136 can be fabricated from a ceramic material such as silicon nitride (e.g., Si₃N₄).

FIG. 1D is a cross-sectional view of FIG. 1B taken along line B-B in FIG. 1B. FIG. 1D shows a retaining mechanism 108 formed in the base 112 in a disengaged position (e.g., a first state). In the disengaged position of the retaining mechanism 108, each spring-loaded member 138 is extended radially inward. The movement member 136 is at least partially disposed inside of the through-bore 106 in the disengaged position of the retaining mechanism 108.

FIG. 1E depicts a cross-sectional view of FIG. 1B taken along line B-B in FIG. 1B when the retaining mechanism 108 is configured in an engaged position (e.g., a second state). In the engaged position of the retaining mechanism 108, the movement members 136 are partially or fully retracted into a respective bore 130. Retraction may be caused, for example, via insertion of a lift pin into the lift pin holder 100. In one or more examples of the engaged position of the retaining mechanism 108, the movement members 136 are flush with the sidewall 126 of the through-bore 106. In other examples of the engaged position of the retaining mechanism, the movement members 136 are contained at least partially within the base 112. In this example, the movement members 136 are at least partially retracted into the base 112 when the lift pin 300 is secured to the lift pin holder 100 via the retaining mechanism 108.

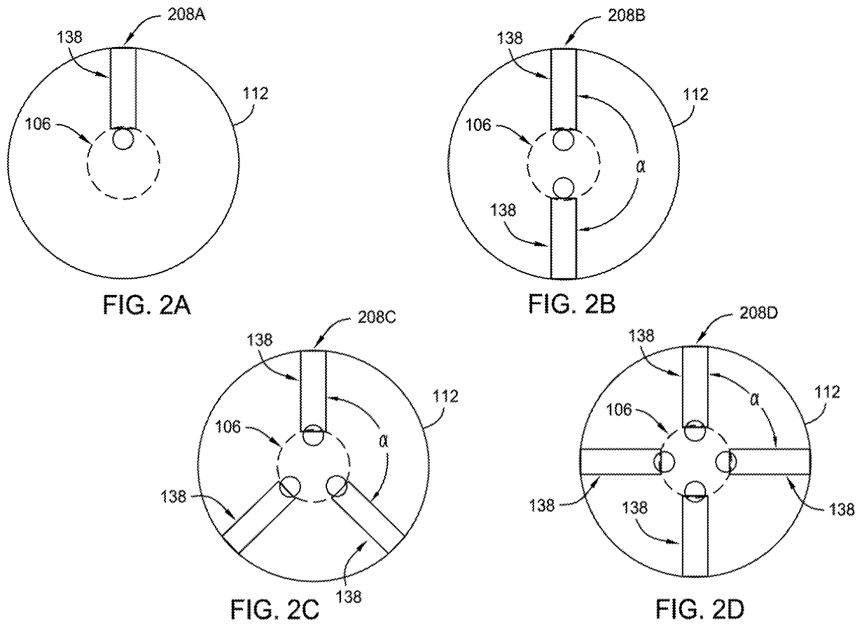

FIGS. 2A-2D depict schematic views of retaining mechanisms 208A, 208B, 208C, 208D in lift pin holders according to embodiments of the present disclosure. The retaining mechanisms 208A-208D are sectional views, shown similarly to the section line B-B of FIG.1B. FIG. 2A shows a retaining mechanism 208A that includes a single spring-loaded member 138. FIG. 2B shows a retaining mechanism 208B that includes two spring-loaded members 138 spaced at an angle of a, which can be about 180°. The angle a can vary from about 10° to about 180°. FIG. 2C shows a retaining mechanism 208C that includes three spring-loaded members 138. As shown in FIG. 2C, each of the three spring-loaded members 138 can be spaced at an angle a of about 120° relative to an adjacent spring-loaded member 138. In other examples, and as shown in FIG. 2D, the retaining mechanism 208D includes four spring-loaded members 138. Each of the four spring-loaded members 138 can be spaced at an angle a of about 90° relative to an adjacent spring-loaded member 138. The examples in 2A-2D shows various configurations of spring-loaded members 138 that are spaced equidistant from adjacent spring-loaded members 138. While the angle a between adjacent spring-loaded members 138 is shown in FIGS. 2A-2D as equidistant, it is contemplated that, in other examples, the angle a may vary between adjacent spring-loaded members 138 within a single retaining mechanism 108.

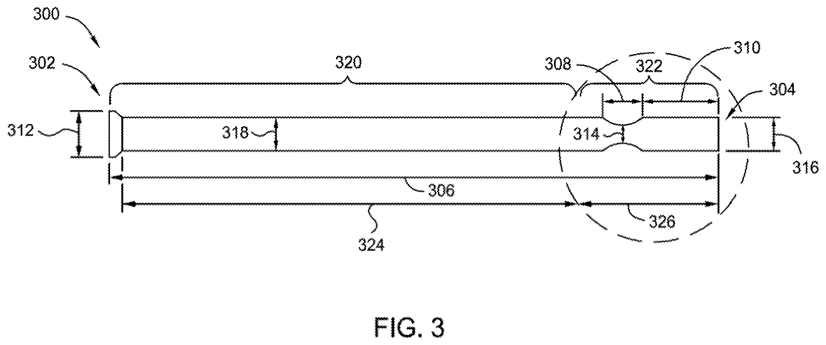

FIG. 3 depicts a schematic view of a lift pin 300 according to embodiments of the present disclosure. The lift pin 300 can be formed from one or more ceramic materials including aluminum oxide (e.g., Al₂O₃). The lift pin 300 includes a first end 302, a second end 304, and a lift pin length 306 extending therebetween. The lift pin 300 includes an elongated portion 320 having an elongated portion length 324 and a second portion 322 having a second portion length 326. The elongated portion 320 has an elongated portion diameter 318. The elongated portion length 324 extends from the first end 302 of the lift pin 300 to the second portion 322. In one or more examples, the elongated portion length 324 of the elongated portion 320 is from about 60% to about 95% of the lift pin length 306. In other examples, the elongated portion length 324 is from about 75% to about 90% of the lift pin length 306. In one or more examples as shown in FIG. 3, the first end 302 of the lift pin 300 can be flared and has a first end diameter 312. In an example where the first end 302 is flared, the elongated portion diameter 318 is less than the first end diameter 312. In some examples, the first end 302 of the lift pin 300 can be flared in order to improve the seating of the lift pin 300 in the substrate support and reduce voids that can be caused by clearance between two adjacent parts. Depending upon the embodiment, the maximum diameter of the lift pin 300 could be the first end diameter 312 or the elongated portion diameter 318, if the first end diameter 312 is different than the elongated portion diameter 318.

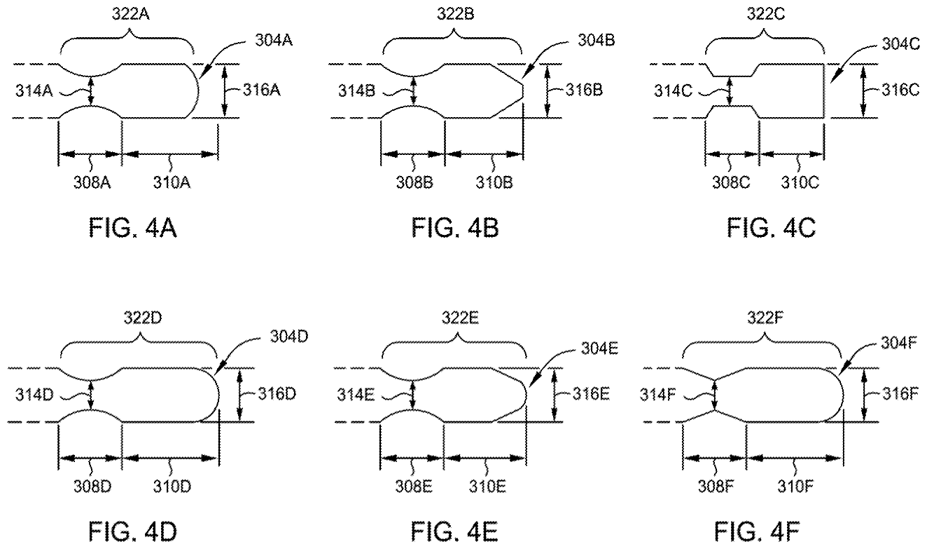

The second portion 322 of the lift pin 300 includes a necking region 308 and a locking mechanism 310. The necking region 308 is positioned such that the elongated portion length 324 extends from the first end 302 of the lift pin 300 to the necking region 308 of the second portion 322, the second portion 322 beginning at the necking region 308. The necking region 308 can have a reduced diameter 314 that is less than the elongated portion diameter 318 by about 5% to about 85%. The locking mechanism 310 of the lift pin 300 can be configured as various geometries, discussed in the below written description in regard to FIGS. 4A-4F. The locking mechanism 310 is the portion of the lift pin 300 that is used in conjunction with the necking region 308 to secure the lift pin 300 in the lift pin holder (100 in FIGS. 1A-1E). Thus, it is contemplated that the second end 304, which includes the locking mechanism 310, can be configured as a blunt end, as shown, or as a rounded, tapered, angled taper, or other geometries or combinations of geometries. In this example, the diameter 316 of the locking mechanism 310 is greater than the reduced diameter 314 of the necking region 308 by, for example, about 5% to about 75%. Depending upon the embodiment, the diameter 316 of the locking mechanism 310 can be less than, greater than, or equal to the elongated portion diameter 318. In one or more examples, the diameter 316 of the locking mechanism 310 differs from the elongated portion diameter 318 by about 1% to about 30%, where a 1% fit is substantially similar to a press-fit.

FIGS. 4A-4F depict partial schematic views of second portions 322A-322F of a lift pin such as the lift pin 300 in FIG. 3. FIGS. 4A-4F show alternate examples of the reduced diameter 314 and the locking mechanism 310. FIG. 4A shows a second portion 322A that includes a necking region 308A having a reduced diameter 314A. The necking region 308A is a tapered region as shown in FIG. 4A. FIG. 4A further shows a second end 304A including a locking mechanism 310A having a diameter 316A. While the second end 304A is shown as a bowed or curved end in FIG. 4A, it is contemplated that the second end 304A could be a blunt end (square or rectangular) or a tapered end in other examples. FIG. 4B shows a second portion 322B including a necking region 308B that has a reduced diameter 314B, and a second end 304B including a locking mechanism 310B that has a diameter 316B. While the second end 304B is shown as a tapered blunt end in FIG. 4B, it is contemplated that the second end 304B could be a blunt end (square or rectangular) or a tapered rounded end in other examples. In various examples, lift pin necking regions 308A and 308B can have different degrees of curvature, resulting in varying reduced diameters 314A and 314B, respectively.

FIG. 4C shows a second portion 322C including a necking region 308C having a reduced diameter 314C, and a second end 304C including a locking mechanism 310C having a diameter 316C. The second end 304C is shown as a tapered blunt end but, in other examples, it is contemplated that the second end 304C could be a blunt end (square or rectangular) or a pointed end with a triangular cross-section. In contrast to the necking regions 308A and 308B that each have a curved cross section, the necking region 308C has a cylindrical inner section of constant diameter, and tapered surfaces at ends of the cylindrical inner section. The tapered surfaces meet at an angled cross section which can take various shapes. In some examples, the necking regions of a lift pin can be selected at least in part based upon the type and geometry of movable elements that will be used in the retaining mechanisms 108 (shown in FIG. 1) discussed herein in order to establish a secure fit of the lift pin in the lift pin holder.

FIG. 4D shows a second portion 322D of a lift pin that includes a necking region 308D having a reduced diameter 314D, and a second end 304D including a locking mechanism 310D having a diameter 316D. The second end 304D is shown as a rounded end that can have a spherical shape, in contrast to what is shown in FIGS. 4A-4C and what is discussed above with respect to blunt and pointed second ends of the lift pin. FIG. 4E shows a second portion 322E including a necking region 308E having a reduced diameter 314E, and a second end 304E including a locking mechanism 310E that has a reduced diameter 316E. The second end 304E is shown as a tapered, rounded end, in contrast to what is shown in FIGS. 4A-4D. As discussed above, the second end 304E can be configured in various geometries including spherical, blunt, tapered, and pointed geometries. Different necking regions can have different degrees of curvature, thus resulting in varying reduced diameters such as 314E. For example, as viewed in the cross-sections of FIGS. 4D and 4E, the curvature of the necking region 308E is greater than a curvature of the necking region 308D. Accordingly, the reduced diameter 314E of the necking region 308E in FIG. 4E is less than the reduced diameter 314D of the necking region 308D in FIG. 4D. While exemplary geometries of the second portions 322A-322F are shown in FIGS. 4A-4F, it is contemplated that, in other examples, other geometries and combinations of geometries are used.

FIG. 4F shows a second portion 322F of a lift pin that includes a necking region 308F that has a reduced diameter 314F, and a second end 304F that includes a locking mechanism 310F having a diameter 316F. The second end 304F is shown as a spherical end but, in other examples, it is contemplated that the second end 304F could be a blunt end (square or rectangular) or a pointed end with a triangular cross-section. In contrast to the necking regions 308D and 308E that each have a curved cross section, the necking region 308F has tapered surfaces that intersect at the reduced diameter 314F.

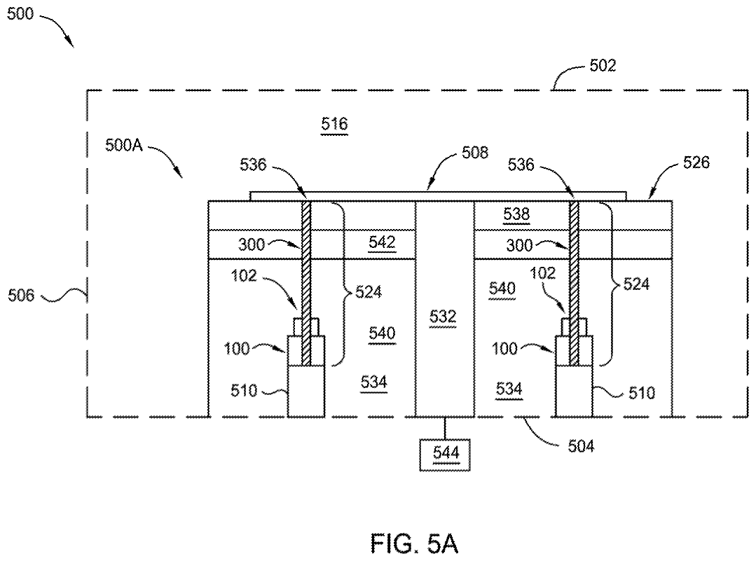

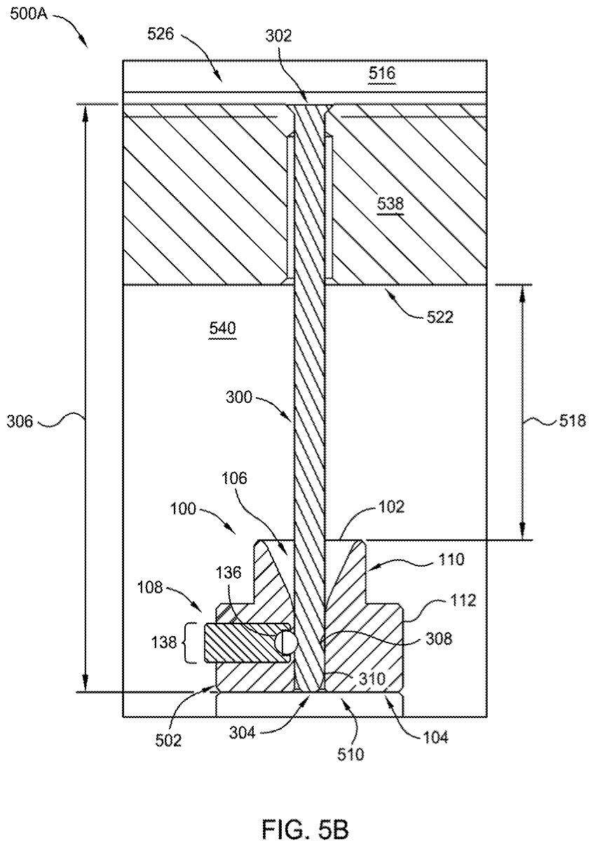

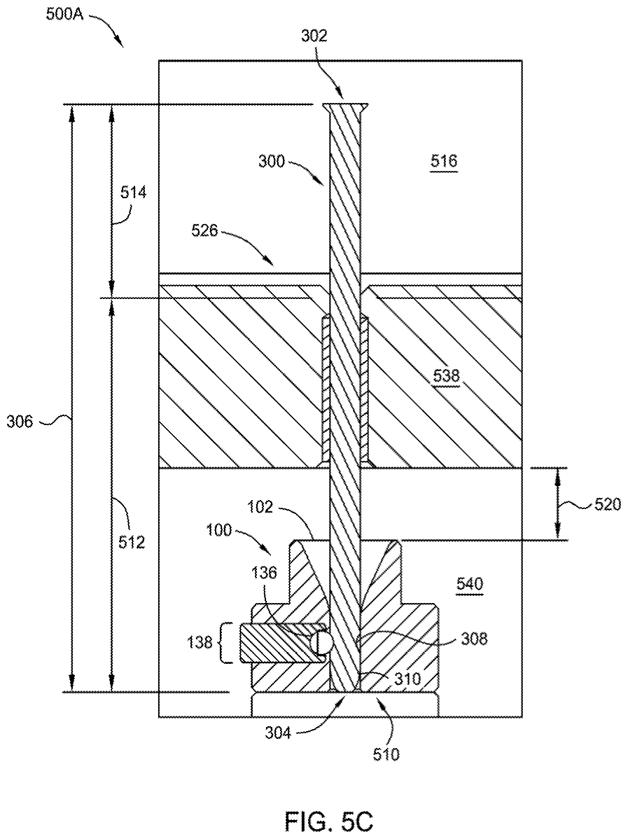

FIG. 5A depicts a partial cross-section view of a process chamber 500 that includes a substrate support 500A, according to embodiments of the present disclosure. The process chamber 500 further has a top 502, a bottom 504, and a sidewall 506. The substrate support 500A includes one or more lift pin holder assemblies 524. A process volume 516 is formed between a top surface 526 of the substrate support 500A and the chamber top 502. A substrate 508 is disposed on the substrate support 500A over the lift pin holder assemblies 524. The substrate 508 can be raised from the substrate support 500A or lowered on to the substrate support 500A via the lift pin holder assemblies 524 by actuating the substrate support 500A to an extended position (raised towards the chamber top 502) or to a retracted position (lowered towards the chamber bottom 504). Various electromechanical devices, such as actuators, motors, stepper motors, and the like, can be employed to raise and lower the substrate support 500A. FIG. 5A shows a substrate support 500A in an extended position where the lift pins 300 of the lift pin holder assemblies 524, do not extend above the top surface 526 of the substrate support 500A. In contrast, and as discussed below, lowering the substrate support 500A to a retracted position causes the lift pins 300 to extend beyond the top surface 526 as shown in FIG. 5C. The process chamber 500 can be configured to execute various processes including chemical vapor deposition (CVD), atomic layer deposition (ALD), or other film deposition or removal processes or other substrate treatment processes. In various examples, the process chamber 500 can be configured to further include gas sources, a gas manifold, a remote plasma source, one or more power sources, and/or other aspects to perform operations including film deposition or removal.

The substrate support 500A includes a support shaft 532 that contains a plurality of electromechanical elements (not shown). Each lift pin holder 100 of each lift pin holder assembly 524 acts to secure the lift pin 300 in, and in some examples below, the substrate support 500A. The lift pin holder 100 further holds those secured lift pins 300 at an angle, such as a right angle, relative to the top surface 526 of the substrate support 500A. Two lift pin holder assemblies 524 are shown in FIG. 5A, but more or less lift pin holder assemblies 524 can be included in a substrate support 500A depending upon the embodiment.

The lift pin holder 100 is coupled to a spacer 510 that can be coupled to the chamber bottom 504 such that the substrate support 500A is raised or lowered during substrate handling without vertical movement of the lift pin holder assemblies 524. In other examples, the spacer 510 can be coupled to a bottom feature of the substrate support 500A (not shown) instead of to the chamber bottom 504. A height of each spacer 510 is selected to position a distal end of each lift pin at a predetermined position relative to an upper surface 526 of the ceramic member 538 when the ceramic member 538 is raised and lowered. The substrate support 500A can further include electrical, mechanical, and electromechanical elements (not shown here) configured to adjust a position, temperature, or other aspect of the substrate support 500A. These electrical, mechanical, and electromechanical elements can be positioned in a volume 534, or otherwise depending upon the embodiment. A ground plate 542 is disposed in contact with a ceramic member 538, and a movement region 540 is formed in between the ground plate 542 and the ceramic member 538. The ceramic member 538 can include one or more heating elements embedded therein. The ceramic member 538 further includes one or more bores 536 where the lift pin 300 is partially retained. For example, the top surface 526 of the substrate support 500A is the top surface of the ceramic member 538.

The ceramic member 538 and the shaft 532 of the substrate support 500A are configured to extend and retract during substrate handling and transfer. The lift pin assemblies 524 are stationary during the extension/retraction since the spacer 510 is coupled to the chamber bottom 504, or another fixed location. In one or more examples, the raising and lowering of the ceramic member 538 is accomplished via one or more electromechanical devices 544, such as actuators. When the ceramic member 538 is retracted towards the chamber bottom 504, for example, using an electromechanical device 544, a distal end of the lift pin 300 of the lift pin holder assembly 524 is positioned beyond the top surface 526 of the substrate support. The ceramic member 538 can subsequently be advanced or extended towards the chamber top 502 to position the distal end of the lift pin 300 at or below the top surface 526 of the substrate support 500A. In some examples, additional elements can be coupled to the ceramic member 538 above or below the ceramic member 538 and can contain bores that are aligned with the bores 536 of the ceramic member 538. Elements coupled to the ceramic member 538 can be advanced and retracted simultaneously with the ceramic member 538. In some examples, the ground plate 542 is optionally in contact with the ceramic member 538 and can be raised and/or lowered along with the ceramic member 538 to expose or contain the lift pin 300. The portion of the substrate support 500A that is raised and/or lowered can be referred to as the movable portion 546. The movable portion 546 can include the ground plate 542, the ceramic member 538, and/or other components (not shown) including insulators. The ground plate 542 and other components of the substrate support 500A can include a bore such that the one or more lift pins 300 can be raised above the top surface 526 of the substrate support 500A.

FIGS. 5B and 5C are partial enlarged views of the substrate support 500A in the extended and retracted positions, respectively, without the optional ground plate 542 shown in FIG. 5A. FIG. 5B shows a lift pin holder assembly 524 when the substrate support 500A is in an extended position. The lift pin 300 is disposed in a through-bore 106 in a lift pin holder 100. A maximum diameter of the lift pin 300 is less than a minimum diameter of the through-bore 106 so that the lift pin 300 fits into the lift pin holder 100. The lift pin 300 is secured to the lift pin holder 100 via a retaining mechanism 108 in the lift pin holder 100. In particular, a movement member 136 of the retaining mechanism 108 engages a necking region 308 of the lift pin 300 to secure the lift pin 300 in the lift pin holder 100. When the lift pin 300 is secured in the lift pin holder 100, the locking mechanism 310 is secured below the retaining mechanism 108 to mitigate inadvertent disengagement of the retaining mechanism 108 from the lift pin 300.

While the substrate support 500A is in the extended position, the lift pin 300 is contained entirely within the substrate support 500A and, thus, does not extend into the process volume 516. When the substrate support is in the extended position, the first holder end 102 is at a first distance 518 from a bottom surface 522 of the ceramic member 538. In the extended position of the substrate support 500A, the first end 302 of the lift pin 300 is flush with or positioned beneath a top surface 526 of the substrate support 500A, as shown in FIG. 5B. A movement region 540 is formed in between the lift pin holder 100 and the ceramic member 538. The movement region 540 includes open space, allowing the ceramic member 538 to move from the extended position in FIG. 5B to the retracted position shown in FIG. 5C. A spacer 510 is coupled to the second holder end 104 of the lift pin holder 100. The second end 304 of the lift pin 300 is in contact with the spacer 510 in this example. The spacer 510 can be fabricated from and/or contain one or more metals or metal-containing materials, such as stainless steel.

FIG. 5C shows a partial view of the substrate support 500A in a retracted position, according to embodiments of the present disclosure. While the substrate support 500A is in the retracted position, the first holder end 102 is at a second distance 520 from a bottom surface 522 of the ceramic member 538. The second distance 520 is less than the first distance 518 in FIG. 5B when the substrate support 500A is shown in the extended position. As shown in FIG. 5C, when the substrate support 500A is in the retracted position, a first length 514 of the lift pin 300 extends above the top surface 526 of the substrate support into the process volume 516, and a second length 512 of the lift pin 300 remains inside of the substrate support 500A. In one or more examples, the first length 514 is from about 15% to about 50% of the lift pin length 306 of the lift pin 300. In other examples, the first length 514 is from about 25% to about 40% of the lift pin length 306. When the substrate support 500A is actuated from the extended position in FIG. 5B to the retracted position in FIG. 5C, the movement member 136 of the retaining mechanism 108 remains in contact with the necking region 308 to secure the lift pin 300 within the lift pin holder 100.

While two positions of the substrate support are shown in FIGS. 5B and 5C, other positions are contemplated such that varying lengths of lift pins 300 in the lift pin holder assemblies 524 can be elevated above the top surface 526 of the ceramic member 538.

Thus, using the systems and methods discussed herein, lift pins can be inserted in and secured to a lift pin holder when the lift pin holder is assembled in a substrate support. The lift pin remains secured to the lift pin holder via the retaining mechanism when the body such as the substrate support is in an extended position or in a retracted position, for example, during substrate handling. The retaining mechanisms in the lift pin holders further allow for the release and replacement of lift pins in the substrate support without disassembling the substrate support, and without damaging the lift pin holder or surrounding components. The lift pin holder assemblies discussed herein are further configured to withstand temperatures of up to 500° C., enabling the use of the lift pin holder assembly across a various process chambers configured to perform operations on the order of about 500° C.

Embodiments of the present disclosure further relate to any one or more of the following paragraphs 1-16:

1. A lift pin holder, comprising: a cap having a first outside diameter; a base coupled to the cap, the base having a second outside diameter; a first bore formed axially through the cap and the base, the first bore having a sidewall; and a plurality of second bores extending from the sidewall of the first bore to an outer surface of the base and a spring-loaded member disposed within each of the second bores.

2. An assembly, comprising: a lift pin comprising: an elongated portion having an elongated portion length and an elongated portion diameter; and a second portion adjacent to the elongated portion and having a locking mechanism; and a lift pin holder comprising: a cap having a first outside diameter; a base coupled to the cap, the base having a second outside diameter; a first bore formed axially through the cap and the base, the first bore having a sidewall; and a plurality of second bores extending from the sidewall of the first bore to an outer surface of the base, a spring-loaded member being disposed within each of the second bores.

3. A substrate support, comprising: a lift pin holder assembly, comprising: a lift pin comprising: an elongated portion having an elongated portion length and an elongated portion diameter; and a second portion adjacent to the elongated portion and having a locking mechanism; and a lift pin holder comprising: a cap having a first outside diameter; a base coupled to the cap, the base having a second outside diameter; a first bore formed axially through the cap and the base, the first bore having a sidewall; and a plurality of second bores extending from the sidewall of the first bore to an outer surface of the base and a spring-loaded member disposed within each of the second bores; and a member coupled to the base of the lift pin holder.

4. The lift pin holder, the assembly, and/or the substrate support according to any one of paragraphs 1-3, wherein the first bore includes a tapered diameter in the cap and a constant diameter in the base.

5. The lift pin holder, the assembly, and/or the substrate support according to any one of paragraphs 1-4, wherein each spring-loaded member comprises a spring and a movable element coupled to the spring, the movable element comprising a ceramic material.

6. The lift pin holder, the assembly, and/or the substrate support according to any one of paragraphs 1-5, wherein each of the cap and the base independently comprises stainless steel.

7. The lift pin holder, the assembly, and/or the substrate support according to any one of paragraphs 1-6, wherein each second bore of the plurality of second bores is at a radial angle from about 10° to about 180° from an adjacent second bore.

8. The lift pin holder, the assembly, and/or the substrate support according to any one of paragraphs 1-7, wherein the lift pin comprises aluminum oxide, and wherein the elongated portion includes a flared end.

9. The lift pin holder, the assembly, and/or the substrate support according to any one of paragraphs 1-8, further comprising a spacer member coupled to the base of the lift pin holder, wherein each of the spacer member, the cap, and the base independently comprises stainless steel.

10. The lift pin holder, the assembly, and/or the substrate support according to any one of paragraphs 1-9, wherein the cap of the lift pin holder has a first bore diameter and the base has a second bore diameter.

11. The lift pin holder, the assembly, and/or the substrate support according to any one of paragraphs 1-10, wherein the second portion of the lift pin has a necking region, a reduced diameter of the necking region being less than the elongated portion diameter, the necking region being adjacent to the locking mechanism.

12. The lift pin holder, the assembly, and/or the substrate support of paragraph 11, wherein the movable element of the spring-loaded member is in contact with the necking region of the lift pin.

13. The lift pin holder, the assembly, and/or the substrate support according to any one of paragraphs 1-12, wherein a minimum diameter of the first bore is greater than the elongated portion diameter of the lift pin.

14. The lift pin holder, the assembly, and/or the substrate support according to any one of paragraphs 1-13, wherein the second portion of the lift pin has a necking region adjacent to the locking mechanism, the necking region having a diameter less than the elongated portion diameter.

15. The lift pin holder, the assembly, and/or the substrate support according to any one of paragraphs 1-14, wherein, when the substrate support is in an extended position, each movable element of each spring-loaded member is engaged with the necking region of the lift pin.

16. The lift pin holder, the assembly, and/or the substrate support of paragraph 15, wherein, when the substrate support is in a retracted position, a first length of the elongated portion of the lift pin is positioned above a top surface of the substrate support and a second length of the elongated portion of the lift pin adjacent to the first length is retained inside of the first bore of the lift pin holder, the lift pin being engaged with the lift pin holder in the retracted position of the substrate support.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A lift pin holder, comprising:
a cap having a first outside diameter;
a base coupled to the cap, the base having a second outside diameter;
a first bore formed axially through the cap and the base, the first bore having a sidewall; and
a plurality of second bores extending from the sidewall of the first bore to an outer surface of the base and a spring-loaded member disposed within each of the second bores.

2. The lift pin holder of claim 1, wherein the first bore includes a tapered diameter in the cap and a constant diameter in the base.

3. The lift pin holder of claim 1, wherein each spring-loaded member comprises a spring and a movable element coupled to the spring, the movable element comprising a ceramic material.

4. The lift pin holder of claim 1, wherein each of the cap and the base independently comprises stainless steel.

5. The lift pin holder of claim 1, wherein each second bore of the plurality of second bores is at a radial angle from about 10° to about 180° from an adjacent second bore.

6. An assembly, comprising:
a lift pin comprising:
an elongated portion having an elongated portion length and an elongated portion diameter; and
a second portion adjacent to the elongated portion and having a locking mechanism; and
a lift pin holder comprising:
a cap having a first outside diameter;
a base coupled to the cap, the base having a second outside diameter;
a first bore formed axially through the cap and the base, the first bore having a sidewall; and
a plurality of second bores extending from the sidewall of the first bore to an outer surface of the base, a spring-loaded member being disposed within each of the second bores.

7. The assembly of claim 6, wherein the lift pin comprises aluminum oxide, and wherein the elongated portion includes a flared end.

8. The assembly of claim 6, wherein the spring-loaded member comprises a spring and a movable element coupled to the spring, the movable element being formed from a ceramic material.

9. The assembly of claim 6, further comprising a spacer member coupled to the base of the lift pin holder, wherein each of the spacer member, the cap, and the base independently comprises stainless steel.

10. The assembly of claim 6, wherein the cap of the lift pin holder has a first bore diameter and the base has a second bore diameter.

11. The assembly of claim 6, wherein the second portion of the lift pin has a necking region, a reduced diameter of the necking region being less than the elongated portion diameter, the necking region being adjacent to the locking mechanism.

12. The assembly of claim 11, wherein the movable element of the spring-loaded member is in contact with the necking region of the lift pin.

13. The assembly of claim 12, wherein each second bore of the plurality of second bores is at a radial angle of about 10° to about 180° from an adjacent second bore.

14. The assembly of claim 12, wherein each spring-loaded member comprises a spring and a movable element comprising ceramic coupled to the spring and positioned radially inward of the spring.

15. The assembly of claim 6, wherein a minimum diameter of the first bore is greater than the elongated portion diameter of the lift pin.

16. A substrate support, comprising:
a lift pin holder assembly, comprising:
a lift pin comprising:
an elongated portion having an elongated portion length and an elongated portion diameter; and
a second portion adjacent to the elongated portion and having a locking mechanism; and
a lift pin holder comprising:
a cap having a first outside diameter;
a base coupled to the cap, the base having a second outside diameter;
a first bore formed axially through the cap and the base, the first bore having a sidewall; and
a plurality of second bores extending from the sidewall of the first bore to an outer surface of the base and a spring-loaded member disposed within each of the second bores; and
a member coupled to the base of the lift pin holder.

17. The substrate support of claim 16, wherein each spring-loaded member comprises a spring and a movable element coupled to the spring, the movable element being formed from a ceramic material.

18. The substrate support of claim 16, wherein the second portion of the lift pin has a necking region adjacent to the locking mechanism, the necking region having a diameter less than the elongated portion diameter.

19. The substrate support of claim 16, wherein, when the substrate support is in an extended position, each movable element of each spring-loaded member is engaged with the necking region of the lift pin.

20. The substrate support of claim 19, wherein, when the substrate support is in a retracted position, a first length of the elongated portion of the lift pin is positioned above a top surface of the substrate support and a second length of the elongated portion of the lift pin adjacent to the first length is retained inside of the first bore of the lift pin holder, the lift pin being engaged with the lift pin holder in the retracted position of the substrate support.
